(19) United States
(12) Patent Application Publication
(10) Pub. No.: US 2008/0001272 A1
(43) Pub. Date: Jan. 3, 2008

(54) System-in-package structure

(76) Inventor: Chi-Chih Chu, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/561,903

(22) Filed: Nov. 21, 2006

(30) Foreign Application Priority Data
Jun. 30, 2006 (TW) 095124037

(51) Int. Cl. H01L 23/02

(52) U.S. Cl. 257/678

(57) ABSTRACT

A system-in-package structure for preventing a solder ball pad from being polluted and a method of fabricating the same are disclosed. The package structure includes a first package and a second package welded with each other. The first package has a carrier with plural solder ball pads and at least one integrated circuits (ICs) electrically connected to the carrier. A groove is formed around each solder ball pad and used to contain the overflowed sealing compound when the ICs are packaged on the first package by a sealing compound, so that the solder ball pad can avoid being polluted by the sealing compound. Thereby, the first package and second package are exactly electrical connected to each other and form a stacking structure.

### BACKGROUND OF THE INVENTION

1. Field of the Invention

The present invention relates to a package structure, and, particularly to a system-in-package structure for preventing a solder ball pad from being polluted.

2. Description of the Prior Art

Please refer to FIGS. 1A to 1D showing cross-sectional schematic diagrams illustrating a conventional system-in-package structure and a fabrication method thereof. As shown in FIG. 1A, a system-in-package structure p1 includes the first package p10 and the second package p20. The first package p10 includes a carrier p11, solder ball pads P1111, and a semiconductor chip p12. A plurality of solder ball pads p1111 are formed on the surface of the carrier p11. The semiconductor chip p12 is electrically connected to the carrier p11. The solder ball pads p1111 are also electrically connected to the semiconductor chip p12 through interconnections within the carrier p11. As shown in FIG. 1B, the semiconductor chip p12 is sealed with sealing compound p13. However, since sealing compound p13 tends to overflow and pollute the solder ball pads p1111, in the subsequent solder ball depositing process, solder balls p112 are not able to attach on the polluted pads p1111, leading some pads p1111 lacking solder balls p112 or the solder ball p112 only partly connects to the pad p1111. As shown in FIGS. 1C and 1D, when the first package 10 is intended to be electrically connected to the second package p20 having same devices therein through the solder balls p112, since, in the first package p10, some of the solder balls p112 are missed or the solder balls p112 are only partly connected to the solder ball pads p1111, some of the solder ball pads p1111 will not be well connected to the solder balls p112 or some of the solder ball pads p1111 with partly connected solder balls p112 fall off during the packaging process, leading the solder ball pads p1111 to be placed in an open circuit condition. Thus, the electric connection of the first package and the second package is failed. The electric connection is a process in the backend of the line. If the failure rate is too high, the cost of loss will increase dramatically.

### SUMMARY OF THE INVENTION

In view of the problem described above, a system-in-package structure for preventing a solder ball pad from being polluted and a method of fabricating the same are provided to solve the problem, such that the pollution to the solder ball pad of the structure from the sealing compound during the packaging process for the semiconductor chip can be avoid.

The system-in-package structure for preventing a solder ball pad from being polluted according to the present invention comprises a first package and a second package. The first package comprises a carrier. The carrier has an upper surface. There are a plurality of solder ball pads on the upper surface, and a plurality of solder balls are deposited on the solder ball pads. At least one groove is formed around each of the solder ball pads. The upper surface is packaged with at least one semiconductor chip electrically connected to the carrier. The second package comprises a carrier. The carrier has an upper surface and a back surface opposite the upper surface. The upper surface is packaged with at least one semiconductor chip electrically connected thereto. The back surface has a plurality of solder balls oppositely soldered to connect to the solder balls on the upper surface of the first package, such that the second package and the first package are stacked up and down, forming a stacking structure.

Among them, the groove on the upper surface of the carrier of the first package may have a cross-section in a regular or an irregular geometric shape.

The method of fabricating a system-in-package structure for preventing a solder ball pad from being polluted according to the present invention comprises steps as follows. A structure is provided. The structure comprises a carrier. The carrier has an upper surface. There are a plurality of solder ball pads on the surface. At least one groove is formed around each of the solder ball pads. At least one semiconductor chip is on the upper surface and electrically connected to the upper surface. A first package is formed by sealing the semiconductor chip and an electrical connecting region on the upper surface of the structure with a sealing material. A second package is provided. The second package comprises a carrier. The carrier has an upper surface and a back surface. The upper surface is packaged with at least one semiconductor chip electrically connected to the upper surface. A plurality of solder balls are deposited on the back surface. The first package and the second package are stacked such that the solder balls of the first package and the solder balls of the second package are oppositely connected to each other. Finally, a solder reflow process is performed to electrically connect the first package to the second package.

Among them, the groove on the upper surface of the carrier of the first package may have a cross-section in a regular or an irregular geometric shape.

Therefore, in the system-in-package structure for preventing a solder ball pad from being polluted and the method of fabricating the same according to the present invention, a groove is formed around each solder ball pad and used to contain the overflowed sealing compound for preventing the solder ball pad from being polluted by the sealing compound. Thereby, when the solder balls are deposited on the solder ball pads, the solder balls can be exactly electrically connected to the solder ball pads, to increase the yield for the subsequent solder reflow process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1A-1D are cross-sectional schematic diagrams showing a conventional system-in-package structure and a fabrication method thereof.

FIG. 2 is a cross-sectional schematic diagram showing a system-in-package structure according to an embodiment of the present invention.

FIG. 3A is a schematic view transferred along line A-A of FIG. 2 and showing a groove around solder ball pads.

FIG. 3B is a schematic diagram showing a groove in an irregular shape in the first package.

FIG. 4 is a schematic diagram showing packaging of the first package using a sealing material.

FIGS. 5A-5D are cross-sectional schematic diagrams showing a method of fabricating a system-in-package structure according to an embodiment of the present invention.

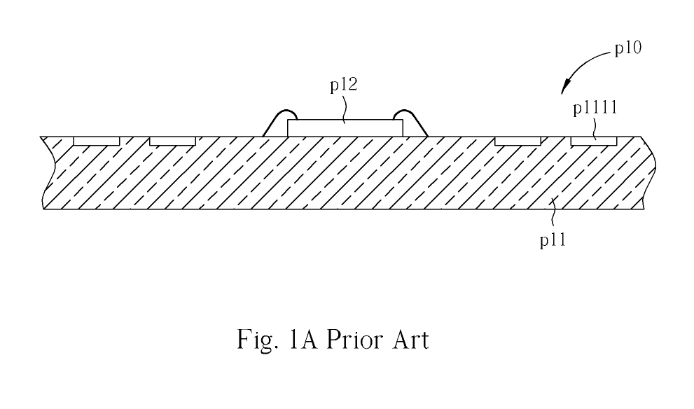

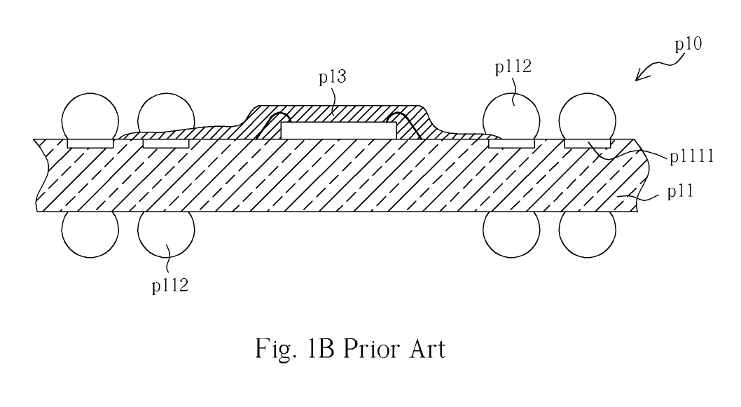

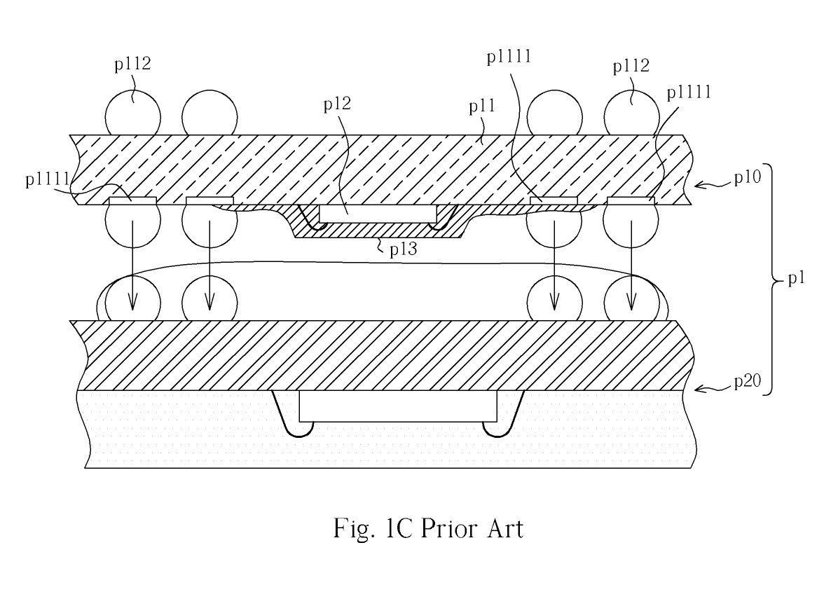

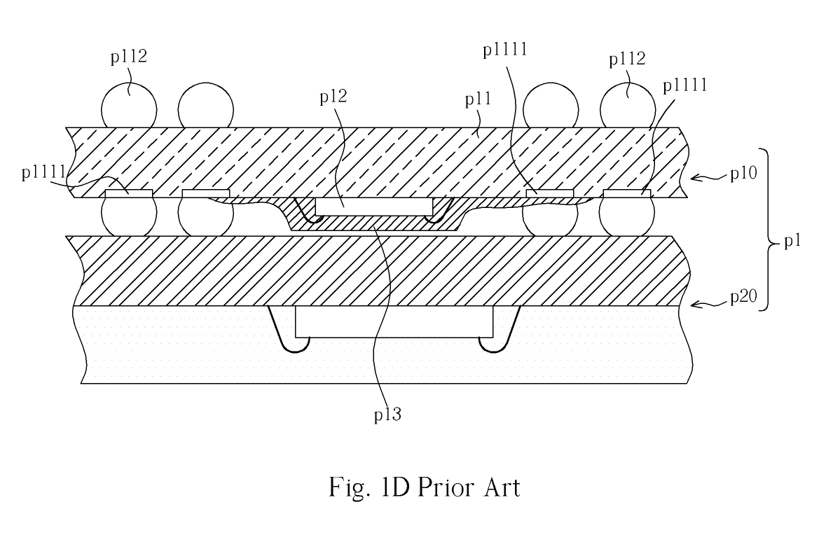

### DETAILED DESCRIPTION

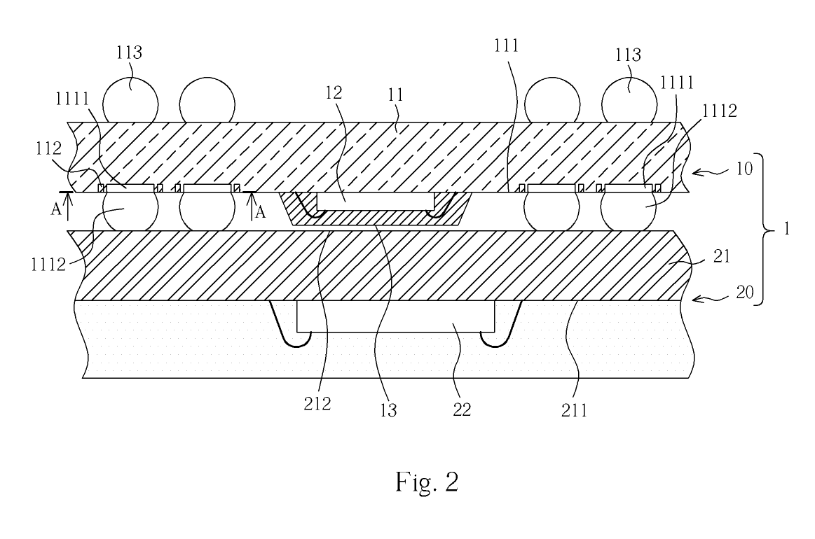

Please refer to FIG. 2, showing a cross-sectional schematic diagram illustrating a system-in-package structure according to an embodiment of the present invention. As shown in FIG. 2, a system-in-package structure 1 having a structure for preventing a solder ball pad from being polluted comprises a first package 10 and a second package 20. The first package 10 comprises a carrier 11. The carrier 11 has an upper surface 111. There are a plurality of solder ball pads 1111 and a solder mask (not shown) on the upper surface 111. The solder mask exposes the solder ball pads 1111. A plurality of solder balls 1112 are deposited on the solder ball pads 1111. In addition, at least one groove 112 is formed around each of the solder ball pads 1111. The groove 112 is preferably formed on the solder mask. The upper surface 111 is packaged with at least one semiconductor chip 12 electrically connected to the carrier 11. The second package 20 likewise comprises a carrier 21. The carrier 21 has an upper surface 211 and a back surface 212 opposite the upper surface 211. The upper surface 211 is packaged with at least one semiconductor chip 22 electrically connected thereto. The back surface 212 has a plurality of solder balls 2121 oppositely soldered to connect to the solder balls 1112 on the upper surface 111 of the first package 10, such that the second package 20 and the first package 10 are stacked up and down, forming a stacking structure. Among them, there are a plurality of solder balls 113 on another surface opposite the upper surface 111, of the first package 10, and the solder balls 113 are electrically connected to the surface. Furthermore, the semiconductor chip 12 on the carrier 11 of the first package 10 and the semiconductor chip 22 on the carrier 21 of the second package 20 have a same function or different functions.

The solder ball serves as a conductor for electrically connecting the first package and the second package. The first package and the second package may both comprise solder balls, but it is also satisfactory that only one of the first package and the second package comprises the solder ball.

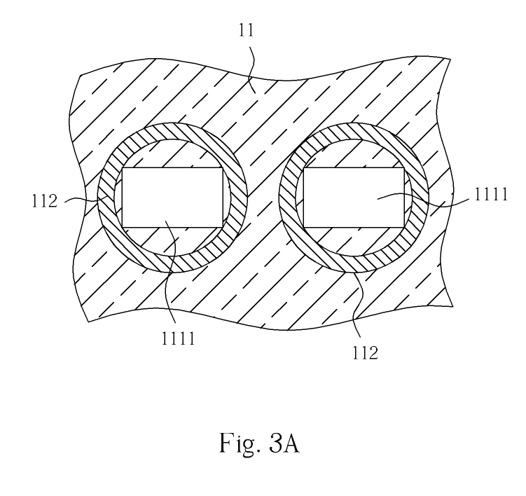

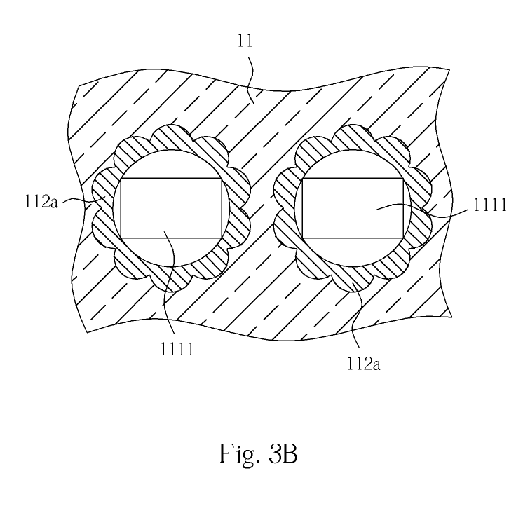

Please refer to FIGS. 3A and 3B showing a schematic view of a groove around solder ball pads transferred along line A-A of FIG. 2 and a schematic diagram illustrating a groove in an irregular shape in the first package. As shown in FIG. 3A, the cross-section shape of the groove 112 on the surface 111 of the carrier 11 of the first package 10 is a regular geometric shape. With respect to this embodiment, the groove 112 is a circular groove. As shown in FIG. 3B, the cross-section shape of the groove 112a on the surface 111 of the carrier 11 of the first package 10 is an irregular geometric shape. With respect to this embodiment, the groove 112a is a petal-like groove. Similarly, grooves can be formed around each of the solder ball pads of the second package, to prevent the solder ball pads from being polluted by undesired material.

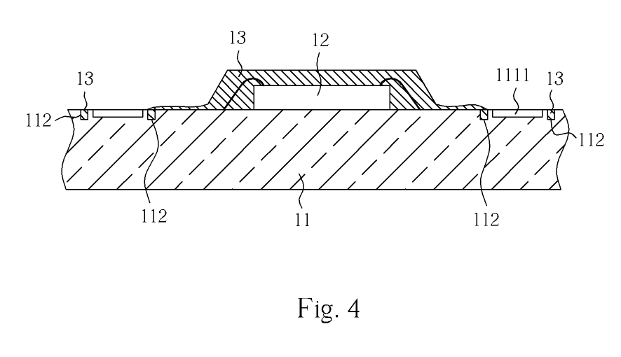

Please refer to FIG. 4 showing a schematic diagram illustrating packaging of the first package using a sealing material or sealing compound. As shown in FIG. 4, after the semiconductor chip 12 is electrically connected to the carrier 11, a sealing process using a sealing material is performed. When the sealing process is performed, in case that a part of sealing material 13 overflows, it can flow into the groove 112 around the solder ball pad 1111 to avoid the sealing material 13 flowing on the solder ball pad 1111, for preventing the solder ball pad 1111 from being polluted by the sealing material 13. Such that, when the first package 10 is subjected to the solder ball depositing process, the failure rate due to the pollution to the solder ball pads 1111 can be reduced and the yield can be increased.

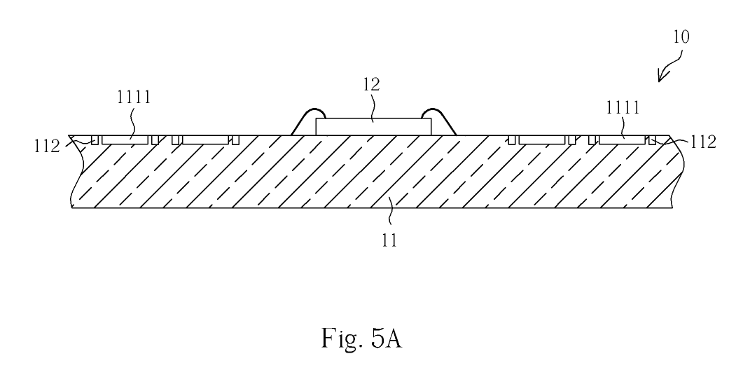

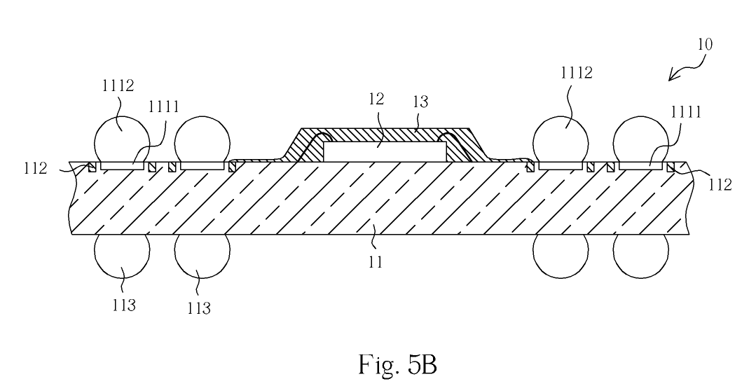

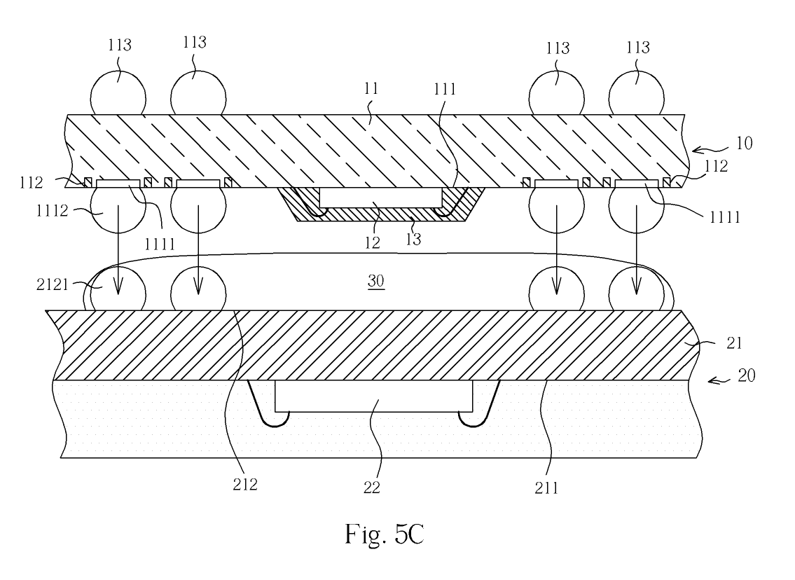

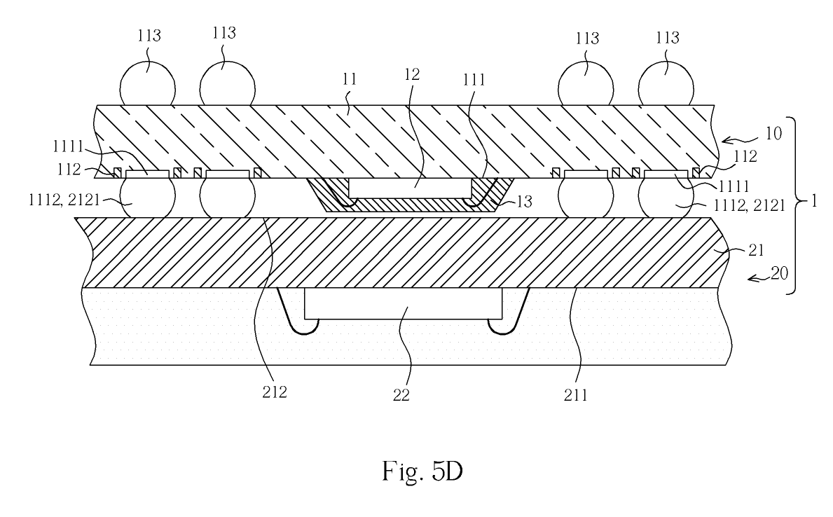

Please refer to FIGS. 5A-5D showing cross-sectional schematic diagrams illustrating a method of fabricating a system-in-package structure according to an embodiment of the present invention. The method of fabricating a system-in-package structure for preventing a solder ball pad from being polluted according to the present invention comprises steps as follows.

First, a structure is provided. The structure comprises a carrier 11. The carrier 11 has an upper surface 111. There are a plurality of solder ball pads 1111 disposed on the surface 111. At least one groove 112 is formed around each of the solder ball pads 1111. At least one semiconductor chip 12 is on the upper surface 111 and electrically connected to the upper surface 111. Next, a first package 10 is formed by sealing the semiconductor chip 12 and an electrical connecting region on the upper surface 111 of the structure with a sealing material. Thereafter, a second package 20 is provided. The second package 20 comprises a carrier 21. The carrier 21 has an upper surface 211 and a back surface 212. The upper surface 211 is packaged with at least one semiconductor chip 22 electrically connected to the upper surface 211. A plurality of solder balls 2121 are deposited on the back surface 212. A solder flux 30 may be applied on the solder balls 2121. The first package 10 and the second package 20 are stacked such that the solder balls 1112 of the first package 10 and the solder balls 2121 of the second package 20 are oppositely connected to each other. A solder reflow process is performed to electrically connect the first package 10 and the second package 20.

Furthermore, the grooves 112 on the upper surface 111 of the carrier 11 of the first package 10 may have a cross-section in a regular geometric shape or an irregular geometric shape.

Furthermore, the semiconductor chip 12 on the carrier 11 of the first package 10 and the semiconductor chip 22 on the carrier 21 of the second package 20 may be semiconductor chips having a same function or different functions.

Therefore, in the system-in-package structure for preventing a solder ball pad from being polluted and the method of fabricating the same according to the present invention, at least one groove is formed around the solder ball pad and used to contain the overflowed sealing material for preventing the solder ball pad from being polluted by the sealing compound.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the true scope and spirit of the invention is indicated by the following claims.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A system-in-package structure, comprising:
a first package comprising:
a carrier having an upper surface with a plurality of solder ball pads thereon;
at least one semiconductor chip disposed on the upper surface of the carrier and electrically connected to the carrier; and
at least one groove formed around each of the solder ball pads; and
a second package comprising:
a carrier having an upper surface and a back surface opposite the upper surface; and
at least one semiconductor chip disposed on the upper surface and electrically connected to the carrier;
wherein the first package and the second package are electrically connected via a conductor.

2. The system-in-package structure of claim 1, wherein the groove on the upper surface of the carrier of the first package has a cross-section in a regular geometric shape.

3. The system-in-package structure of claim 1, wherein the groove on the upper surface of the carrier of the first package has a cross-section in an irregular geometric shape.

4. The system-in-package structure of claim 1, wherein the first package has another surface opposite the upper surface, having a plurality of solder balls electrically connected thereto.

5. The system-in-package structure of claim 1, wherein the semiconductor chip in the first package and the semiconductor chip in the second package are semiconductor chips having a same function or different functions.

6. The system-in-package structure of claim 1, wherein the upper surface of the carrier of the first package further comprises a solder mask exposing the solder ball pad s.

7. The system-in-package structure of claim 6, wherein the groove is formed on the solder mask.

8. The system-in-package structure of claim 1, wherein the conductor comprises a first solder ball.

9. The system-in-package structure of claim 8, wherein the first solder ball is deposited on each of the solder ball pads of the upper surface of the first package.

10. The system-in-package structure of claim 9, wherein the second package further comprises a second solder ball on the back surface of the second package and electrically connected to the first solder ball.
